(19) United States
(12) Patent Application Publication
(10) Pub. No.: US 2024/0384393 A1
(43) Pub. Date: Nov. 21, 2024

(54) HARD COATING, HARD-COATING COATED TOOL, AND PRODUCTION METHOD FOR HARD COATING

(71) Applicant: OSG CORPORATION, Toyokawa-shi, Aichi (JP)

(72) Inventors: Yoshitaka ADACHI, Toyokawa-shi (JP); Hiroki GIMA, Toyokawa-shi (JP); Hiroaki SUGITA, Toyokawa-shi (JP)

(73) Assignee: OSG CORPORATION, Toyokawa-shi, Aichi (JP)

(21) Appl. No.: 18/689,332

(22) PCT Filed: Sep. 30, 2021
(86) PCT No.: PCT/JP2021/036132

§ 371 Date: Mar. 5, 2024

(51) Int. Cl. C23C 14/18; C22C 21/00; C23C 14/35

(52) U.S. Cl. CPC C23C 14/185; C22C 21/00; C23C 14/35

(57) ABSTRACT

A hard coating includes first and second layers. The first layer is constituted by AlₐCr_{b}α_{c}N, wherein atomic ratios a, b, c satisfy a+b+c=1, 0≤c≤0.40 and 0.25≤b/a≤1.0, and an optional additive component α is at least one kind of element selected from groups IVa, Va and VIa (except Cr) and Y of periodic table of elements. The second layer is constituted by Al_{d}CrₑC_{f}N, wherein atomic ratios d, e, f satisfy d+e+f=1, 0.001≤f≤0.20 and 0.25≤ e/d≤1.0. A total thickness T of a thickness T1 of the first layer and a thickness T2 of the second layer is 0.5-9.0 μm. A ratio of the thickness T2 to the total thickness T is 5-50%. The hard coating has peaks belonging to (111) and (200) planes in an X-ray diffraction, such that an intensity ratio of a peak intensity SP1 of the (111) plane to a peak intensity SP2 of the (200) plane is 0.1-20.

### TECHNICAL FIELD

The present invention relates to a hard coating for coating a surface of a substrate, a hard-coating coated tool coated with the hard coating, and a method of producing the hard coating.

### BACKGROUND ART

There is proposed a technique of covering a surface of a substrate with a hard coating, for improving wear resistance, adhesion resistance and durability, for example, in various members, i.e., various machining tools such as a cutting tool (e.g., tap, drill, endmill, milling cutter, lathe cutter) and a non-cutting tool (e.g., thread forming tap, rolling tool, press die) and also various tool members such as a friction part requiring the wear resistance. A hard coating disclosed in each of Patent Documents 1 and 2 is an example of such a hard coating. In each of the Patent Documents 1 and 2, there is proposed a technique of constituting the hard coating using AlCrN, AlCrCN or the like.

### PRIOR ART DOCUMENTS

### Patent Documents

[Patent Document 1] Japanese Patent No. 6383333

[Patent Document 2] Japanese Patent No. 5090251

### DISCLOSURE OF THE INVENTION

### Object to be Achieved by the Invention

However, in such a conventional hard coating, there is a case in which sufficient durability cannot be necessarily obtained due to occurrence of chipping, peeling or the like of the coating, depending on a machining condition or a usage condition, for example, so that there is still a room for improvement. For example, when a tapping operation was performed in SCM440 (chrome molybdenum steel) specified by JIS, by using a thread forming tap coated with AlCrN, the number of holes machined was less than 1000, and sufficient durability was not obtained.

The present invention was made in view of the background discussed above. It is therefore an object of the present invention to further improve durability of AlCrN-based hard coating.

### Measures for Achieving the Object

For achieving the object, a first invention is, in a hard coating that is to be provided on a surface of a substrate so as to cover the surface of the substrate, characterized in that (a) the hard coating includes a first layer to be disposed on the surface of the substrate and a second layer disposed on a surface of the first layer, (b) the first layer is constituted by AlₐCr_{b}α_{c}N, wherein atomic ratios a, b, c satisfy a+b+c=1, 0≤c≤0.40 and 0.25≤b/a≤1.0, and wherein an optional additive component α is at least one kind of element selected from groups IVa, Va and VIa (except Cr) and Y of periodic table of elements, (c) the second layer is constituted by AlCrₑC_{f}N, wherein atomic ratios d, e, f satisfy d+e+f=1, 0.001≤f≤0.20 and 0.25≤e/d≤1.0, (d) a total thickness T as a sum of a thickness T1 of the first layer and a thickness T2 of the second layer is within a range from 0.5 μm to 9.0 μm, and a ratio (T2/T) of the thickness T2 of the second layer to the total thickness T is within a range from 5% to 50%, and (e) the hard coating including the first layer and the second layer has peaks belonging to (111) and (200) planes in an X-ray diffraction, such that an intensity ratio (SP1/SP2) of a peak intensity SP1 of the (111) plane to a peak intensity SP2 of the (200) plane is within a range from 0.1 to 20.

It is noted that a value obtained by multiplying each of the above-described atomic ratios a-f by 100 is at % (atom %).

A second invention is, in a hard-coating coated tool in which a hard coating is provided on a surface of a substrate, is characterized in that the hard coating is the hard coating according to the first invention.

A third invention is, in a method of producing the hard coating according to the first invention, is characterized in that (a) both of the first layer and the second layer are formed by a high-power pulse magnetron sputtering method, and (b) the second layer is formed by sputtering with use of AlCr alloy as a target by supplying nitrogen gas and hydrocarbon gas into a chamber, such that the atomic ratio f of the Cis not lower than 0.001 and is not higher than 0.20 by adjusting an amount of supply of the hydrocarbon gas.

The above-described high-power pulse magnetron sputtering method is a coating formation technique called HiPIMS (abbreviation for High-Power Impulse Magnetron Sputtering), and is hereinafter referred to as HiPIMS method.

### Effects of the Invention

According to the hard coating of the first invention and the hard-coating coated tool of the second invention, excellent durability can be obtained. Where the AlCrN-based hard coating is formed in accordance with arch ion plating method, minute droplets called macroparticles adhere to inside or surface of the coating, thereby causing adhesion of the workpiece and chipping or peeling of the coating, and resulting in possible reduction of the durability of the hard coating. However, according to the HiPIMS method, the macroparticles are reduced whereby adhesion resistance and chipping resistance are increased and the durability is further increased.

### BRIEF DESCRIPTION OF DRAWINGS

FIG. 1 is a front view showing, by way of example, a thread forming tap to which the present invention is applied.

FIG. 2 is an enlarged cross-sectional view as seen along arrows II-II in FIG. 1.

FIG. 3 is a cross sectional view for explaining a coating structure of a hard coating provided in the thread forming tap of FIG. 1.

FIG. 4 is a view for explaining an example of a sputtering device for coating a substrate with the hard coating of FIG. 3 in accordance with HiPIMS method.

FIG. 5 is a view for explaining result of study of relationship between a supply ratio of methane gas (CH4) and carbon content when the substrate is coated with a second layer with use of the sputtering device of FIG. 4.

FIG. 6 is a view showing, by way of example, an intensity distribution obtained by X-ray diffraction for the hard coating that is an embodiment of the present invention.

FIG. 7 is a view for explaining a plurality of test products No. 1 to No. 40 that are different in the coating structure of the hard coating, and showing a composition of a first layer of the hard coating.

FIG. 8 is a view showing a composition of the second layer, thicknesses and result of X-ray diffraction (XRD) in the plurality of test products No. 1 to No. 40 of FIG. 7.

FIG. 9 is a view for explaining result of study of durability and cause of lifespan by performing tapping operations with use of the test products No. 1 to No. 40 shown in FIGS. 7 and 8.

### MODES FOR CARRYING OUT THE INVENTION

The present invention is advantageously applied to a hard coating which is to be disposed on a surface of a substrate, in a hard-coating coated tool, namely, in any one of various machining tools that include cutting tools such as a tap, a drill, an endmill, a milling cutter and a lathe cutter, and non-cutting tools such as a thread forming tap (that is also known as thread rolling tap), a rolling tool and a press die. Further, the present invention can be applied to a hard coating of, in addition to the machining tools, any one of various members such as a bearing member which require wear resistance and adhesion resistance. It can be applied also to a tip of a tip replaceable tool in which the tip is removably attached to a body of the tool.

As the coating method, i.e., the method of producing the hard coating of the present invention, it is possible to use an electron-beam evaporation method and a physical vapor deposition method (PVD method) such as hollow cathode method, magnetron sputtering method (MS method) and arc-ion plating method (AIP method). The MS method uses a glow discharge created by applying a voltage to a cathode in which a magnet and a target are placed in a rare gas atmosphere, to cause accelerated ions to collide with the target, and to cause a coating material to be released from the target by their kinetic energy, such that the released material is caused to adhere to the substrate. In this case, it is possible to form a smooth coating as compared with the electron-beam evaporation method (in which droplets are generated due to thermal shock), the hollow cathode method and the AIP method. The MS method is categorized to DCMS method and HiPIMS method. In the DCMS method, a direct voltage (DC) is applied to the cathode. In the HiPIMS method, a capacitor and a switch are placed between a DC voltage power source and the cathode, and high power pulses are applied to the cathode by charging and discharging the capacitor. In the HiPIMS method in which large electric power is supplied to the cathode, it is possible to generate plasma with a higher ionization rate than in the DCMS method. As the method of producing the hard coating of the present invention, the HiPIMS method as a kind of the sputtering method is preferably used, wherein AlCr alloy is used as the target, AlCrN as the first layer is formed in a mixed gas atmosphere of Ar and N₂, and then AlCrCN as the second layer is formed by further introducing hydrocarbon gas. Where AlCrαN containing the optional additive component α is provided as the first layer, AlCrα alloy may be used as the target for forming the first layer.

The AIP method is a method that uses arc discharge to evaporate or ionize the target from a solid state, and then forms the coating on the substrate. In the AIP method in which extremely high energy is supplied to the target, the coating with high adhesion and wear resistance can be obtained, while impact of the arc discharge causes a large amount of macro particles called droplets and having a size of several μm or more, to adhere to the substrate or surface of the coating. In order to reduce fly of the droplets, there is also a method of filtering, and in that case, it is suitably used as the method of producing the hard coating of the present invention. Thus, it is possible to employ a coating technique such as this AIP method, which is other than the above-described HiPIMS method.

### Embodiment

Hereinafter, an embodiment of the present invention will be described in detail with reference to drawings. In the drawings of the embodiment, the drawings are simplified or modified as needed, and dimensional ratios, shapes, angles and the like of various parts are not necessarily accurately drawn.

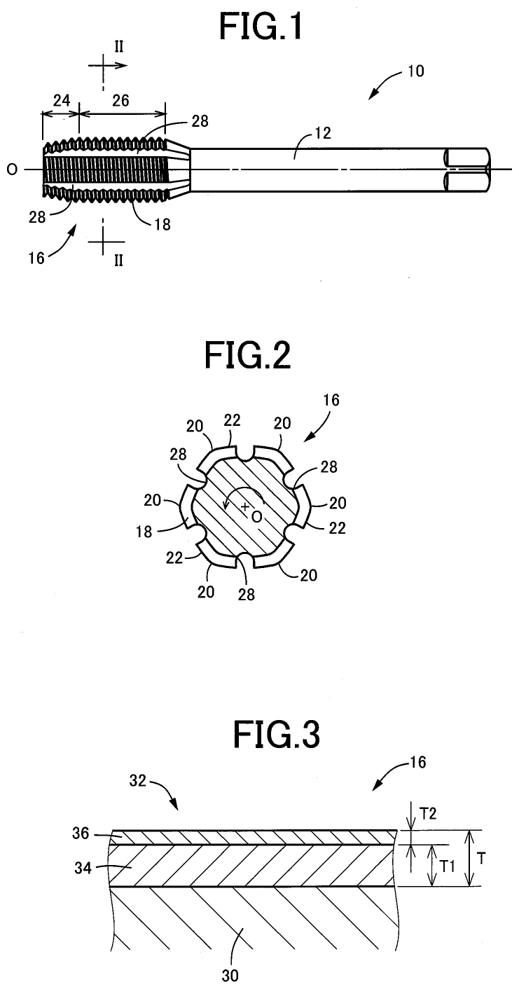

FIG. 1 is a front view showing a thread forming tap 10 to which the present invention is applied, wherein the front view is as seen in a direction perpendicular to an axis O of the tap 10. FIG. 2 is a view showing, in enlargement, a cross section of a thread portion 16 as seen along arrows II-II in FIG. 1. This thread forming tap 10 includes, in addition to the thread portion 16 provided to form (roll) an internal thread, a shank portion 12 that is to be attached into a spindle of a tapping machine (not shown), such that the thread portion 16 and the shank portion 12 are integrally contiguous and coaxial with each other in an axial direction (i.e., direction parallel to the axis O). The thread portion 16 has a polygonal shape with outwardly curved sides, and has a substantially regular hexagonal cross section in the present embodiment. The thread portion 16 has an external thread on its outer peripheral surface, so that the external thread is to be caused to bite into an inner-wall surface layer of a prepared hole of a workpiece (female screw material) and to plastically deform the inner-wall surface layer, for thereby forming the internal thread.

A thread ridge 18 of the external thread provided in the thread portion 16 has a cross sectional shape corresponding to a shape of a valley of the internal thread that is to be formed, and extends along a helix having a lead angle of the internal thread. The thread portion 16 includes six protruding portions 20 and six relieved portions 22 that are alternately arranged in a helical direction in which the thread ridge 18 extends. The protruding portions 20, in each of which the thread ridge 18 protrudes radially outwardly, are arranged equiangularly about the axis O at an angular pitch of 60°. The relieved portions 22, each of which has a small diameter and is contiguous to a corresponding one of the protruding portions 20 in the helical direction, are arranged equiangularly about the axis O at an angular pitch of 60°. That is, the multiplicity of protruding portions 20 are arranged in six lines that correspond to respective vertexes of the regular hexagonal shape, such that the protruding portions 20 of each of the six lines are successively arranged in the axial direction, and such that the six lines of the protruding portions 20 are arranged equiangularly about the axis O. It is noted that FIG. 2 is a view of a cross section taken along the helix at a valley of the thread ridge 18.

The thread portion 16 includes a complete thread portion 26 having a diameter that is substantially constant in the axial direction, and a leading portion 24 having a diameter that is reduced in a direction toward a distal end of the thread portion 16. In the leading portion 24, an outside diameter, an effective diameter and a root dimeter of the external thread are changed at respective constant rates that are equal to one another. In the leading portion 24, too, the thread portion 16 has a substantially regular hexagonal shape in its cross section, as shown in FIG. 2, and includes the protruding portions 20 and the relieved portions 22 that are alternately arranged in a circumferential direction about the axis O. Further, in the outer circumferential surface of the thread portion 16, there are provided oil grooves 28 through which a lubricant fluid is to be supplied, such that each of the oil grooves 28 is located in an intermediate position between each adjacent two of the six lines of the protruding portions 20 in the circumferential direction about the axis O. The number of the oil groove 28 may be one, and the oil groove 28 may be omitted.

The thread forming tap 10 constructed as described above is to be screwed into a prepared hole formed in a workpiece with the leading portion 24 being first introduced into the prepared hole, whereby the protruding portions 20 are caused to bite into an inner-wall-surface layer portion of the prepared hole, so as to cause the inner-wall-surface layer portion to be plastically deformed for thereby forming an internal thread. In such a tapping operation by the thread forming tap 10, a large rotational torque is required, and wear and adhesion could be caused in the thread portion 16 due to friction between the thread portion 16 and the workpiece, so that there is a possibility that the tap 10 could not have a sufficient tool life depending on a machining condition.

On the other hand, in the thread forming tap 10 of the present embodiment, the thread portion 16 is coated with a hard coating 32 that covers a surface of a substrate 30 of the tap 10, as shown in FIG. 3. The substrate 30 may be made of cemented carbide, high-speed tool steel or other tool material, and is made of high-speed tool steel, in the present embodiment. The hard coating 32 includes a first layer 34 disposed on the surface of the substrate 30 and a second layer 36 disposed on a surface of the first layer 34. The second layer 36 constitutes a surface of the hard coating 32. The thread forming tap 10 corresponds to a hard-coating coated tool.

To describe the hard coating 32 specifically, the first layer 34 is constituted by AlₐCr_{b}α_{c}N, wherein atomic ratios a, b, c satisfy a+b+c=1, 0≤c≤0.40 and 0.25≤b/a≤1.0, and wherein an optional additive component α is at least one kind of element selected from groups IVa, Va and VIa (except Cr) and Y. The second layer 36 is constituted by Al_{d}CrₑC_{f}N, wherein atomic ratios d, e, f satisfy d+e+f=1, 0.001≤f≤0.20 and 0.25≤e/d≤1.0. Further, a total thickness T as a sum of a thickness T1 of the first layer 34 and a thickness T2 of the second layer 36 is within a range from 0.5 μm to 9.0 μm, and a ratio (T2/T) of the thickness T2 of the second layer 36 to the total thickness T is within a range from 5% to 50%. Further, the hard coating 32 has peaks belonging to (111) and (200) planes in an X-ray diffraction (hereinafter referred also to as “XRD”), such that an intensity ratio (SP1/SP2) of a peak intensity SP1 of the (111) plane to a peak intensity SP2 of the (200) plane is within a range from 0.1 to 20.

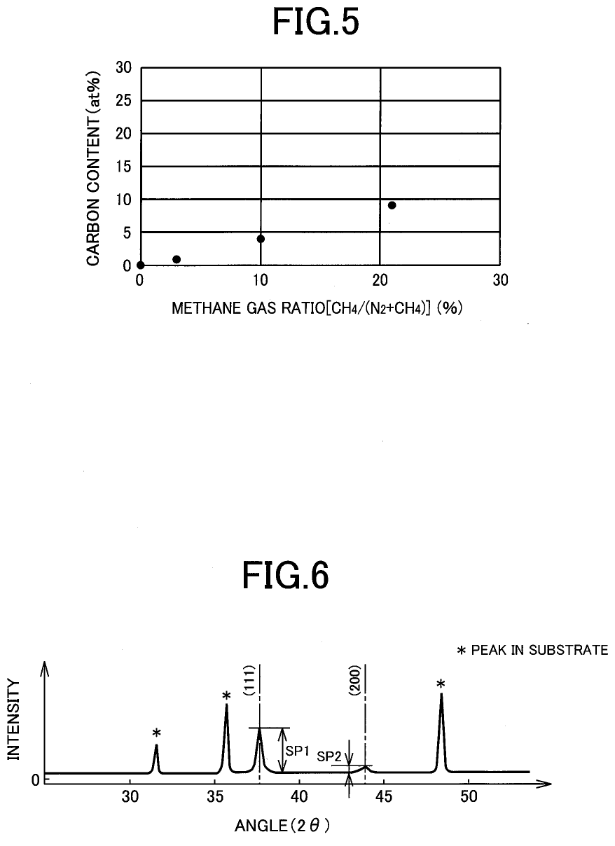

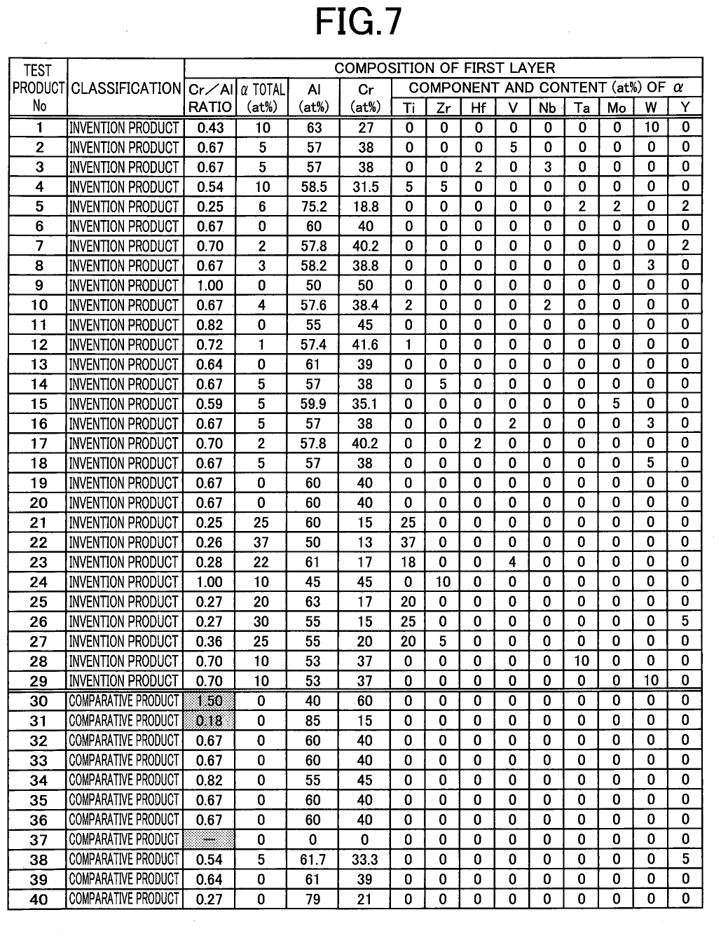

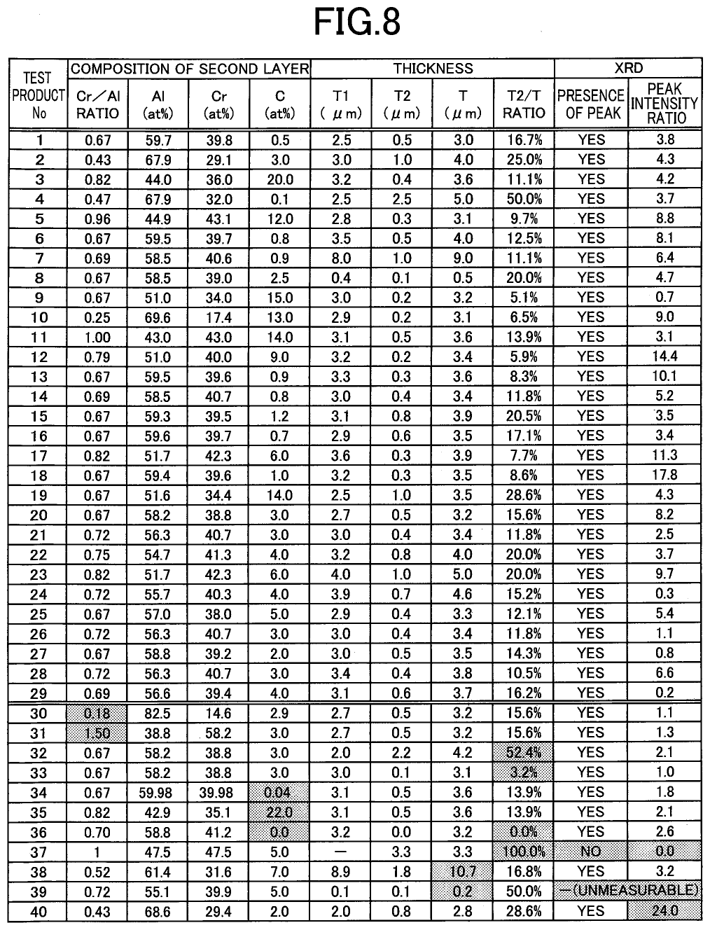

FIG. 6 is a view showing, by way of example, an intensity distribution measured by using an X-ray diffractometer manufactured by PANalytical under the following measurement condition, and is measurement result of test product No. 7 shown in FIGS. 7 and 8. “θ” is a diffraction angle, and a peak in the (111) plane is a peak that appears in angular range of 2θ=37° to 39°, and a peak in the (200) plane is a peak that appears in angular range of 2θ=43.5° to 44.5°. Peak intensities SP1 and SP2 are values measured based on an intensity of a base part between peaks as shown in FIG. 6, and an intensity ratio (SP1/SP2) in a case of FIG. 6 (test product No. 7) is 6.4 (see FIG. 8). In FIG. 8, “PRESENCE OF PEAK” in column of “XRD” (i.e., X-ray diffraction) indicates whether the peak in the (111) plane is present or not, and “PEAK INTENSITY RATIO” indicates the above-described intensity ratio (SP1/SP2). The peak in the (200) plane is always present regardless of the coating structure of first layer 34 and second layer 36. It is noted that the peaks marked with an asterisk “*” in FIG. 6 are those derived from a cemented-carbide test piece substrate, and that results of “XRD” (i.e., X-ray diffraction) in FIG. 8 are results obtained by forming the same hard coating 32 as the test products No. 1 to No. 40 on the cemented-carbide test piece substrate.

### Measurement Condition

tube voltage: 45 kV
tube current: 40 mA
X-ray source: CuKa (0.15060 nm)
divergence slit: ⅛°
antiscatter slit: 1°, 25°-55°

FIGS. 7 and 8 are views for explaining the plurality of test products No. 1 to No. 40 that are different in the coating structure of the hard coating 32, wherein each of the test products No. 1 to No. 29 is an invention product that satisfies requirements of the hard coating 32 while each of the test products No. 30 to No. 40 is a comparative product that does not satisfy at least one of the requirements of the hard coating 32. In the test products No. 30 to No. 40, which are the comparative products, items with dots mean that they are deviated from the requirements of the hard coating 32. The thickness T2 of the second layer 36 of the test product No. 36 is 0.0, because carbon content of the second layer 36 is 0.0 at % and is essentially composed of AlCrN so that the thickness of the second layer 36 is included in the thickness TI of the first layer 34. It is noted that the hard coating in each of the comparative products, which does not satisfy at least one of the requirements of the hard coating 32, will also be referred to as the hard coating 32 in the following description.

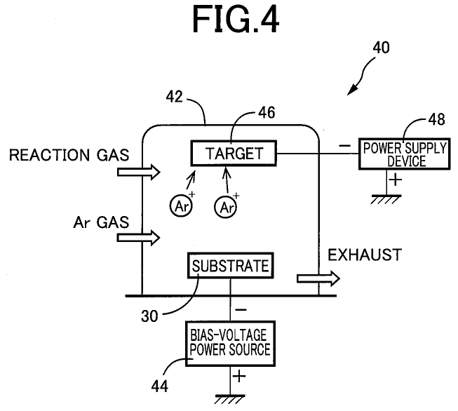

There will be next described a coating method, namely, a method of producing the above-described hard coating 32. In the present embodiment, the hard coating 32 is coated on the substrate 30 in accordance with HiPIMS method. FIG. 4 is a conceptual view for explaining an example of a sputtering device capable of performing the HiPIMS method. This sputtering device 40 includes a chamber 42, a bias-voltage power source 44, a target 46 and a power supply device 48. The target 46 uses AlCr alloy that constitutes the hard coating 32. Where the first layer 34 does not include the optional additive component α, it is sufficient to use one kind of the target 46 made of the AlCr alloy. Where the first layer 34 includes the optional additive component α, it is sufficient to use two kinds of the targets 46, one of which is made of AlCrα alloy for forming the first layer 34, and another one of which is made of the AlCr alloy for forming the second layer 36. The target 46 is placed in a cathode along with a magnet. A negative voltage is applied to the target 46 by the power supply device 48, whereby ions (Ar+) accelerated by a glow discharge are made to collide with the target 46, and their kinetic energy causes a coating material AlCrα or AlCr to be released from the target 46 and to adhere to the substrate 30 to which a negative bias voltage is applied by the bias-voltage power source 44. The power supply device 48 is provided with a capacitor and a switch circuit in addition to a DC voltage power supply, and is configured to apply large power pulses with a peak power density of 0.1 kW/cm² or higher, for example, to the cathode, by charging and discharging the capacitor. Specifically, the hard coating 32 is formed under a condition in which, for example, the cathode input power is 5 kW to 55 kW, the degree of vacuum is 0.5 Pa to 2.0 Pa, ON time of the pulse waveform is 20 μs to 4000 μs and OFF time of the pulse waveform is 150 μs to 12000 μs. Thus, plasma with a high ionization rate is generated so that the hard coating 32 having a high smoothness with few macroparticles owing to the high-density plasma, an excellent adhesion resistance, an excellent wear resistance and an excellent heat resistance is formed.

When the first layer 34 is to be formed, it is possible to form the first layer 34 of AlCrαN, by introducing nitrogen gas (N₂) as a reaction gas into the chamber 42. When the second layer 36 is to be formed, it is possible to form the second layer 36 of AlCrN, by introducing nitrogen gas (N₂) and methane gas (CH₄) as reaction gases into the chamber 42. The methane gas may be replaced by another hydrocarbon gas. The atomic ratio f of the C can be set in a range of 0.001 to 0.20, by adjusting an amount of supply of the methane gas. FIG. 5 is a view for explaining study of relationship between the carbon content and a supply ratio [CH₄/(N₂+CH₄)] of CH₄ to a total flow amount of N₂+CH₄. The carbon content in the second layer 36 is increased with increase of the supply ratio of the methane gas. Thus, the carbon content in the second layer 36 can be increased to 20 at %, for example, as indicated in the test product No. 3 shown in FIG. 8.

The carbon content can be determined, for example, by SIMS method (secondary ion mass spectrometry). The carbon content (at %) in the second layer 36 shown in FIG. 8 is result of measurement using the SIMS method. A device used for the measurement is PHIADEPT1010 (manufactured by ULVAC-PHI, Inc.), a primary ion species is Cs+, a primary acceleration voltage is 5.0 kV, a detection area is 24 μm×24 μm, and a standard sample for quantification is AlN. FIG. 5 shows results of carbon content measurement results for four types of test products No. 12, No. 22, No. 7 and No. 36 that are different in the amount of supply of the methane gas in formation of the second layer 36. In the test product No. 12, the CH₄ supply ratio [CH₄/(N₂+CH₄)] was 21% and the carbon content was approximately 9.0 at %. In the test product No. 22, the CH₄ supply ratio [CH₄/(N₂+CH₄)] was 10% and the carbon content was approximately 4.0 at %. In the test product No. 7, the CH₄ supply ratio [CH₄/(N₂+CH₄)] was 3% and the carbon content was approximately 0.9 at %. In the test product No. 36, the CH₄ supply ratio [CH₄/(N₂+CH₄)] was 0% without introduction of CH₄, namely, the second layer 36 was constituted by AlCrN, and the carbon content was approximately 0.01 at %.

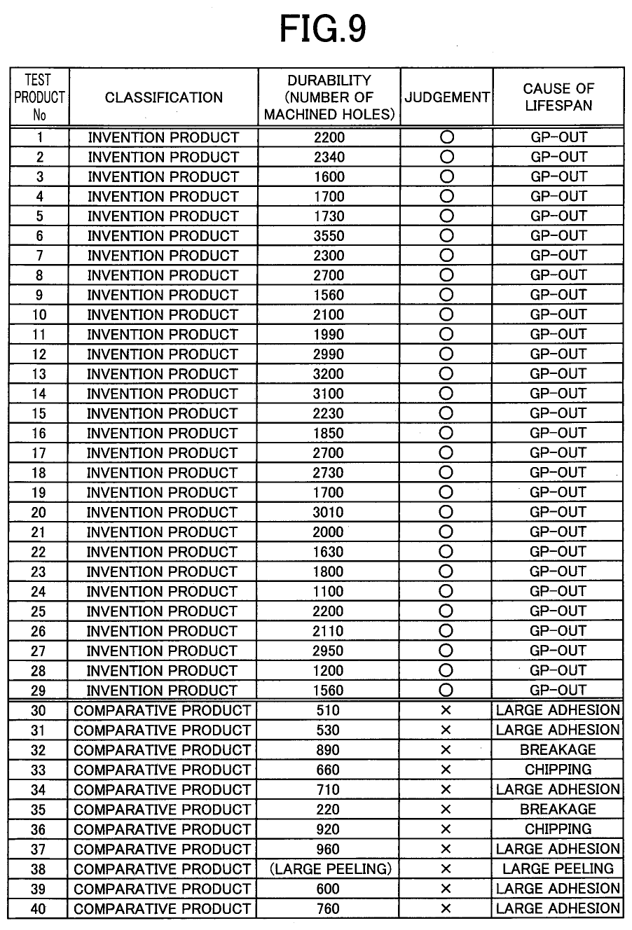

FIG. 9 is a view for explaining result of study of durability and cause of lifespan by performing tapping operations with use of the test products No. 1 to No. 40 shown in FIGS. 7 and 8, wherein the tapping operations were performed under a machining condition as indicated below, and a number of holes machined until the end of the tool life was reached was checked as the durability. In the machining condition, SCM440 as “workpiece” is a steel material symbol according to JIS standards that represents chromium molybdenum steel, and HRC is Rockwell C hardness. D in “tapping length” is a tool diameter, which in this case is 6 mm, and 2D=12 mm. It is noted that the hard coating 32 is formed with use of the HiPIMS method, all in the test products No. 1 to No. 40 including comparative products that do not satisfy the requirements of the hard coating 32.

### Machining condition

Thread size: M6×1.0
Workpiece: SCM440 (30 HRC)
Cutting speed: 15 m/min
Tapping length: 2D
Cutting fluid: water-soluble cutting fluid, 20 times diluted, external lubrication

In FIG. 9, in column of “JUDGMENT”, “◯” means pass and “x” means fail, wherein those with the number of machined holes machined being 1000 or more were qualified as passing the test. In column of “CAUSE OF LIFESPAN”, “GP-OUT” is a case in which a thread plug gauge (GP) could not pass through the machined hole, with the effective diameter of the internal thread being reduced due to wear of the hard coating 32. As is clear from the results in FIG. 9, the test products No. 1 to No. 29, which are products of the present invention, all passed the test because they were capable of machining more than 1000 holes. In all of the test products No. 1 to No. 29, the cause of lifespan was GP-OUT due to wear of the hard coating 32. On the other hand, all in the test products No. 30 to No. 40, which are the comparative products that do not satisfy the requirements of the hard coating 32, the number of machined holes machined was less than 1000, due to adhesion, chipping, peeling or the like of the coating. Thus, the comparative products are inferior to the invention products with respect to the durability.

Thus, the thread forming tap 10 of the present embodiment, which is coated with the hard coating 32, has excellent durability. In addition, where the AlCrN-based hard coating is formed in accordance with AIP method, minute droplets called macroparticles (each having a diameter of 1 μm or more, for example) adhere to inside or surface of the coating, thereby causing adhesion of the workpiece and chipping or peeling of the coating, and resulting in possible reduction of the durability. However, in the present embodiment, the hard coating 32 is formed with use of the

HiPIMS method, so that the macroparticles are reduced whereby the adhesion resistance and chipping resistance are increased and the durability is further increased.

The present inventors and their collaborators checked the number of macroparticles with the diameter of 1 μm or more, which existed on the surface of the hard coating 32, by using a scanning electron microscope, and they found that the number of the macroparticles was not more than 1/10 as compared with the case in which the AlCrN-based hard coating was formed in accordance with the AIP method.

While the embodiment of the present invention has been described in detail by reference to the accompanying drawings, it is to be understood that the described embodiment is merely an embodied form and that the present invention can be embodied with various modifications and improvements on the basis of knowledge of those skilled in the art.

### DESCRIPTION OF REFERENCE SIGNS

10: thread forming tap (hard-coating coated tool)
30: substrate
32: hard coating
34: first layer
36: second layer
40: sputtering device
42: chamber
46: target

1. A hard coating that is to be provided on a surface of a substrate so as to cover the surface of the substrate, wherein
the hard coating includes a first layer to be disposed on the surface of the substrate and a second layer disposed on a surface of the first layer,
the first layer is constituted by AlₐCr_{b}α_{c}N, wherein atomic ratios a, b, c satisfy a+b+c=1, 0≤c≤0.40 and 0.25≤b/a≤1.0, and wherein an optional additive component α is at least one kind of element selected from groups IVa, Va and VIa (except Cr) and Y of periodic table of elements,
the second layer is constituted by AlCrₑCN, wherein atomic ratios d, e, f satisfy d+e+f=1, 0.001≤f<0.20 and 0.25≤e/d≤1.0,
a total thickness T as a sum of a thickness T1 of the first layer and a thickness T2 of the second layer is within a range from 0.5 μm to 9.0 μm,
a ratio (T2/T) of the thickness T2 of the second layer to the total thickness T is within a range from 5% to 50%, and
the hard coating including the first layer and the second layer has peaks belonging to (111) and (200) planes in an X-ray diffraction, such that an intensity ratio (SP1/SP2) of a peak intensity SP1 of the (111) plane to a peak intensity SP2 of the (200) plane is within a range from 0.1 to 20.

2. A hard-coating coated tool in which a hard coating is provided on a surface of a substrate, wherein
the hard coating is the hard coating according to claim 1.

3. A method of producing the hard coating according to claim 1, wherein
both of the first layer and the second layer are formed by a high-power pulse magnetron sputtering method, and
the second layer is formed by sputtering with use of AlCr alloy as a target by supplying nitrogen gas and hydrocarbon gas into a chamber, such that the atomic ratio f of the C is not lower than 0.001 and is not higher than 0.20 by adjusting an amount of supply of the hydrocarbon gas.
